(19) United States
(12) Patent Application Publication
(10) Pub. No.: US 2015/0279683 A1
(43) Pub. Date: Oct. 1, 2015

(54) METHOD AND APPARATUS FOR FORMING TiSiN FILM

(71) Applicant: TOKYO ELECTRON LIMITED, Tokyo (JP)

(72) Inventor: Katsushige HARADA, Nirasaki City (JP)

(21) Appl. No.: 14/670,730

(22) Filed: Mar. 27, 2015

(30) Foreign Application Priority Data
Mar. 31, 2014 (JP) 2014-071699

(51) Int. Cl. H01L 21/285; C23C 16/52; C23C 16/46; H01L 49/02; C23C 16/455

(52) U.S. Cl. CPC H01L 21/28556; H01L 21/28568; H01L 28/60; C23C 16/45544; C23C 16/46; C23C 16/52; C23C 16/45557

(57) ABSTRACT

Provided is a method of forming a TiSiN film on a surface of an object to be processed, the method including: repeating a first cycle a first predetermined number of times, the first cycle including supplying Ti raw material gas containing Ti raw material into a processing chamber, and supplying nitriding gas containing a nitridant into the processing chamber after the Ti raw material gas is supplied into the processing chamber; and repeating a second cycle a second predetermined number of times after repeating the first cycle the first predetermined number of times, the second cycle including supplying Si raw material gas containing Si raw material into the processing chamber, and supplying nitriding gas containing a nitridant into the processing chamber after the Si raw material gas is supplied into the processing chamber, wherein the Si raw material gas comprises an amine-based Si raw material gas.

### CROSS-REFERENCE TO RELATED APPLICATION

This application claims the benefit of Japanese Patent Application No. 2014-071699, filed on Mar. 31, 2014, in the Japan Patent Office, the disclosure of which is incorporated herein in its entirety by reference.

### TECHNICAL FIELD

The present disclosure relates to a method and apparatus for forming a TiSiN film.

### BACKGROUND

A titanium nitride (TiN) film is a conductive film and is used in applications such as electrodes of a capacitor. Typically, TiN film is used as a lower electrode (i.e., a storage electrode) of a capacitor in a memory cell of a DRAM. Due to the development of three-dimensional structures in memory cells, thermal CVD or thermal ALD techniques are used to form TiN films as lower electrodes of capacitors. Tetrachlorotitanium (TiCl₄), which has excellent step coverage, is used as a titanium raw material, and ammonia (NH₃) is used as a nitridant is employed.

Recently, memory cells are becoming smaller. Accordingly, TiN films used in memory cells require improved chemical resistance and oxidation-resistance. TiSiN films, which are TiN films doped with silicon (Si), have been proposed in order to improve the chemical resistance and oxidation-resistance properties of TiN film.

In general, a chlorine (Cl)-based silicon raw material, such as DCS (dichlorosilane: SiH₂Cl₂) or TCS (trichlorosilane: SiHCl₃), which both have the same structure as that of the TiCl₄ used to form the TiN film, is used to dope the TiN film with Si.

When a TiN film is doped with Si, although chemical resistance and oxidation-resistance properties are improved compared to a TiN film without being doped with Si, the specific resistivity of the Si doped TiN film is higher. In order to obtain a TiSiN film with better conductivity, as well as chemical and oxidation-resistance, it is important to have the Si concentration be controlled.

However, Cl-based silicon raw materials have good reactivity and high film formation rates. Therefore, a thick Si film forms on the TiN film when Cl-based silicon raw materials are used. This makes it difficult to precisely control the Si concentration.

### SUMMARY

Some embodiments of the present disclosure provide a TiSiN film-forming method where the Si concentration can be more finely controlled, and a film forming apparatus capable of executing such a method.

According to one embodiment of the present disclosure, there is provided a method of forming a TiSiN film on a surface of an object to be processed, the method including: repeating a first cycle a first predetermined number of times, the first cycle including supplying a Ti raw material gas containing Ti raw material into a processing chamber where the object to be processed is accommodated, and supplying nitriding gas containing a nitridant into the processing chamber after the Ti raw material gas is supplied into the processing chamber; and repeating a second cycle a second predetermined number of times after repeating the first cycle the first predetermined number of times, the second cycle including supplying a Si raw material gas containing Si raw material into the processing chamber, and supplying a nitriding gas containing a nitridant into the processing chamber after the Si raw material gas is supplied into the processing chamber, wherein the Si raw material gas comprises an amine-based Si raw material gas.

According to another embodiment of the present disclosure, there is provided a film forming apparatus for forming a TiSiN film on a surface of an object to be processed, the apparatus including: a processing chamber that accommodates the object to be processed; a gas supply mechanism that supplies a Ti raw material gas, a nitriding gas, and an amine-based Si raw material gas into the processing chamber; a heating unit that heats an interior of the processing chamber; an exhaust unit that exhausts the interior of the processing chamber; and a controller that controls the gas supply mechanism, the heating unit, and the exhaust unit, wherein the controller controls the gas supply mechanism, the heating unit, and the exhaust unit so that the aforementioned method is performed on the object to be processed in the processing chamber.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating an example of a method of forming a TiSiN film in accordance with a first embodiment of the present disclosure.

FIGS. 2A to 2E are cross-sectional views, which schematically illustrate the states of an object undergoing the process illustrated in FIG. 1.

FIG. 3 is a diagram illustrating the relationship between the type of Si raw material gas and Si concentration.

FIG. 4 is a diagram illustrating the relationship between the number of cycles and the thickness of a SiN film.

FIG. 5 is a diagram comparing the characteristics of a TiN film and a TiSiN film.

FIG. 6 is a longitudinal cross-sectional view schematically illustrating the first example of a film forming apparatus in accordance with the second embodiment of the present disclosure.

FIG. 7 is a horizontal cross-sectional view schematically illustrating the second example of a film forming apparatus in accordance with the second embodiment of the present disclosure.

### DETAILED DESCRIPTION

Reference will now be made in detail to various embodiments, examples of which are illustrated in the accompanying drawings. Hereinafter, some embodiments of the present disclosure are described with reference to the accompanying drawings. Furthermore, the same reference numerals are used to refer to the same elements throughout the drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

### <Film Forming Method>

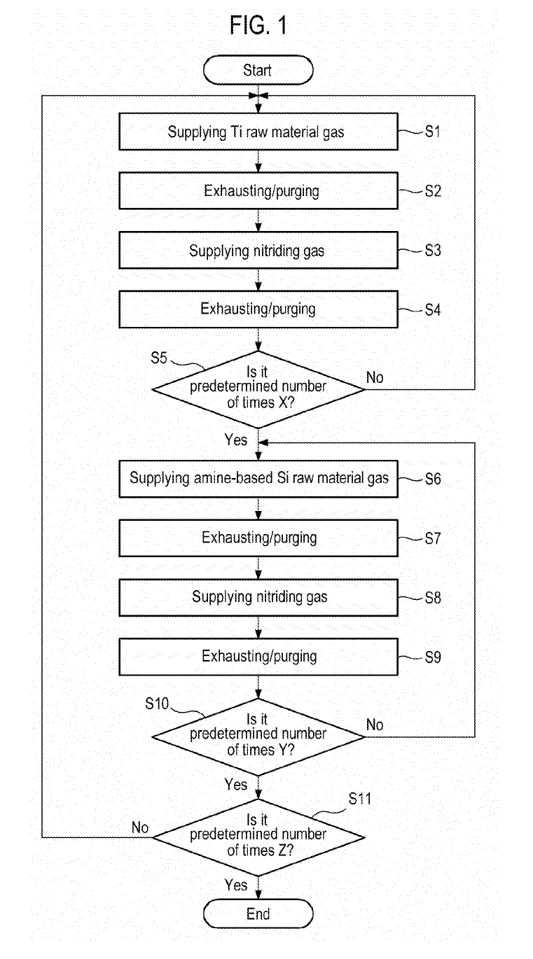

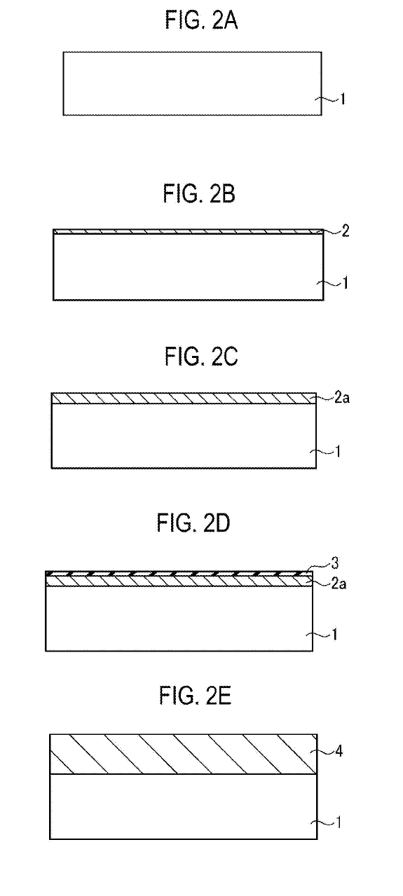

FIG. 1 is a flowchart illustrating an example of a method of forming a TiSiN film according to the first embodiment of the present disclosure, and FIGS. 2A to 2E are cross-sectional views which schematically illustrate the states of an object undergoing the process illustrated in FIG. 1.

First, the object to be processed is accommodated in the processing chamber of a film forming apparatus. An example of an object to be processed may be a silicon wafer (referred hereinafter to as “wafer”) 1, as illustrated in FIG. 2A.

Subsequently, as illustrated in Step S1 of FIG. 1, a Ti raw material gas, such as a gas containing TiCl₄, is supplied into the processing chamber. Accordingly, Ti is deposited on the surface of wafer 1, thus forming a Ti layer.

An example of processing conditions in Step S1 is as follows:

Flow Rate of TiCl₄: 100 sccm

Processing Time: 5 seconds

Processing Temperature: 400 degrees C.

Processing Pressure: 39.99 Pa (0.3 Torr). Furthermore, in this specification, 1 Torr is defined as 133.3 Pa.

Subsequently, as illustrated in Step S2 of FIG. 1, the Ti raw material gas is exhausted from the processing chamber, and then the inside of the processing chamber is purged using an inert gas. An example of the inert gas may include nitrogen (N₂) gas.

Subsequently, as illustrated in Step S3 of FIG. 1, a nitriding gas containing a nitridant is supplied into the processing chamber. An example of the nitridant may include a gas containing ammonia (NH₃). As illustrated in FIG. 2B, the Ti layer formed on the surface of the wafer 1 to be processed is nitrided into a titanium nitride (TiN) layer 2.

An example of processing conditions in Step S3 is as follows:

Flow Rate of NH₃: 10 slm

Processing Time: 15 seconds

Processing Temperature: 400 degrees C.

Processing Pressure: 133.3 Pa (1.0 Torr).

Subsequently, as illustrated in Step S4 of FIG. 1, the nitriding gas is exhausted from the processing chamber, and then the inside of the processing chamber is purged using an inert gas.

Subsequently, as illustrated in Step S5 of FIG. 1, it is determined whether Steps S1 to S4 have been repeated a predetermined number of times X. If it is determined that Steps S1 to S4 have not been repeated the predetermined number of times X (the “No” branch of Step S5), the process returns to Step S1, and Steps S1 to S4 are repeated. By repeating Steps S1 to S4 as described above (i.e., until Steps S1 to S4 are repeated the predetermined number of times X), a TiN layer 2a with a predetermined thickness is formed on the surface of the wafer 1 to be processed, as illustrated in FIG. 2C. If it is determined that Steps S1 to S4 have been repeated the predetermined number of times X (the “Yes” branch of Step S5), the process proceeds to Step S6.

As illustrated in Step S6 of FIG. 1, an amine-based Si raw material gas containing silicon (Si) is supplied into the processing chamber. An example of the amine-based Si gas may include a gas containing 3DMAS (tris(dimethylamino)silane: SiH[N(CH₃)₂]₃). Accordingly, Si is deposited on the TiN layer 2a, thus forming a Si layer.

An example of processing conditions in Step S6 is as follows:

Flow Rate of 3DMAS: 0.4 sccm

Processing Time: 20 seconds

Processing Temperature: 400 degrees C.

Processing Pressure: 39.99 Pa (0.3 Torr).

Subsequently, as illustrated in Step S7 of FIG. 1, the Si raw material gas is exhausted from the processing chamber, and then the inside of the processing chamber is purged using an inert gas.

Subsequently, as illustrated in Step S8 of FIG. 1, a nitriding gas is supplied into the processing chamber. The nitriding gas in Step S8 may be the same gas as used in Step S3. Accordingly, as illustrated in FIG. 2D, the Si layer formed on the TiN layer 2a is nitrided into a silicon nitride (SiN) layer 3.

An example of processing conditions in Step S8 is as follows:

Flow Rate of NH₃: 10 slm

Processing Time: 40 seconds

Processing Temperature: 400 degrees C.

Processing Pressure: 133.3 Pa (1.0 Torr).

Subsequently, as illustrated in Step S92 of FIG. 1, the nitriding gas is exhausted from the processing chamber, and then the inside of the processing chamber is purged using an inert gas.

Subsequently, as illustrated in Step S10 of FIG. 1, it is determined whether Steps S6 to S9 have been repeated a predetermined number of times Y. If it is determined that Steps S6 to S9 has not been repeated the predetermined number of times Y (the “No” branch of Step S10), the process returns to Step S6, and Steps S6 to S9 are repeated. By repeating Steps S6 to S9 as described above (i.e., until Steps S6 to S9 is repeated the predetermined number of times Y), a SiN layer 3 with a predetermined thickness is formed on the TiN layer 2a. If it is determined that Steps S6 to S9 have been repeated the predetermined number of times Y (the “Yes” branch of Step S10), the process proceeds to Step S11.

Furthermore, in this example, the predetermined number of times Y has been set to “1.” Steps S6 to S9 need not to be repeated as described above.

As illustrated in Step S11 of FIG. 1, it is determined whether Steps S1 to S4 and Steps S6 to S9 have been repeated a predetermined number of times Z. If it is determined that Steps S1 to S4 and the set of Steps S6 to S9 have not been repeated the predetermined number of times Z (the “No” branch of Step S11), the process returns to Step S1, and Steps S1 to S4 and Steps S6 to S9 are repeated. By repeating Steps S1 to S4 and Steps S6 to S9 as described above until Steps S1 to S4 and Steps S6 to S9 are repeated the predetermined number of times Z, a TiSiN film 4 with a predetermined thickness is formed on the surface of the wafer 1 to be processed, as illustrated in FIG. 2E. If it is determined that Steps S1 to S4 and Steps S6 to S9 have been repeated the predetermined number of times Z (the “Yes” branch of Step S11), the formation of TiSiN film according to the first embodiment is complete.

### <Advantages>

In the method of forming a TiSiN film according to the first embodiment, an amine-based Si raw material gas is used as the Si raw material gas to form the Si layer in Step S6. The formation of the Si layer using an amine-based Si raw material gas lowers the film formation rate compared to the case of using a Cl-based Si raw material gas, for example. Therefore, a thinner Si layer can be formed. One of the reasons why the film formation rate of an amine-based Si raw material gas is lower than a Cl-based gas is that the Si-N bond has a bonding energy of 105 kcal/mol, which is higher than the 77 kcal/mol bonding energy of a Si-Cl bond.

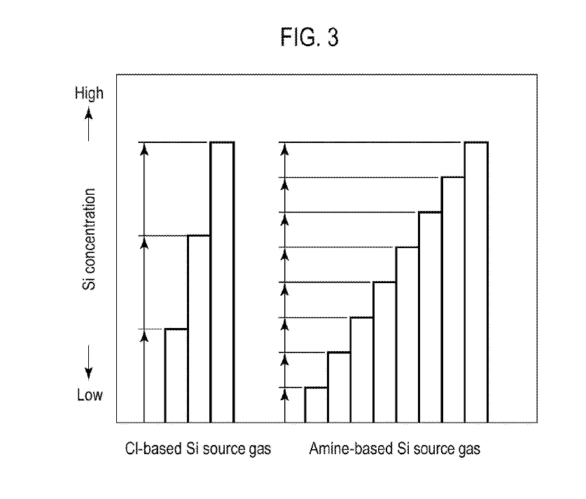

FIG. 3 illustrates the relationship between the type of Si raw material gas and Si concentration.

As illustrated in FIG. 3, the film formation rate is higher for a Cl-based Si raw material gas (used as the Si raw material gas) than an amine-based Si raw material gas. As a result, the minimum film thickness film for a Cl-based gas is thicker than for an amine-based Si raw material gas used as the Si raw material gas. The thickness of the Si layer determines the amount of Si doped into the TiN film. As the Si layer becomes thicker, more Si is doped into the TiN film. Therefore, as the minimum film thickness increases, the amount of Si in each Si layer also increases. This results in poor control of the Si concentration as illustrated in FIG. 3.

If an amine-based Si raw material gas is used as a Si raw material gas instead of a Cl-based Si raw material gas, the minimum film thickness becomes lower. Accordingly, the Si concentration can be more precisely controlled as illustrated in FIG. 3. Furthermore, the minimum amount of Si that can be doped is lower compared to when a Cl-based Si raw material gas is used as the Si raw material gas.

Furthermore, since the Si concentration can be more precisely controlled, the chemical resistance, oxidation-resistance properties, and the specific resistivity of the TiSiN film can be tuned with higher precision.

As described above, the first embodiment of the present disclosure provides a method of forming a TiSiN film where the Si concentration can be more precisely controlled.

### <Ti Catalyst Effect>

It is difficult to form a Si layer using an amine-based Si raw material gas, on a Si base such as a Si substrate.

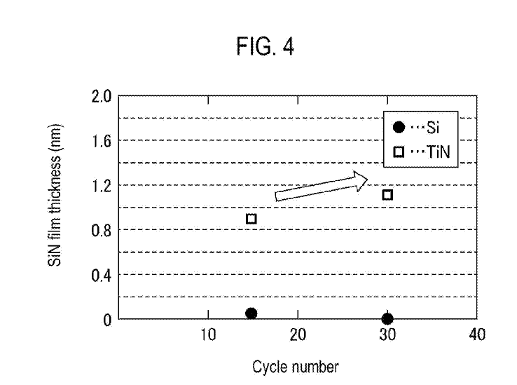

FIG. 4 illustrates the relationship between the cycle number, i.e., the number of times Steps S6 to S9 of FIG. 1 are repeated, and the thickness of the SiN film. In FIG. 4, the same Steps S6 to S9 were performed under the same processing conditions on a Si substrate and on a TiN film. The film thickness of the SiN films that were formed on the surfaces were compared. with the film thickness of the SiN film that was formed on the TiN film.

As illustrated in FIG. 4, if an amine-based Si raw material gas was used as a Si raw material gas, the SiN film was rarely formed on the Si substrate. In contrast, by cycle number 15, an SiN film of about 0.9 nm was formed on the TiN film. By cycle number 30, the SiN film on the TiN film was about 1.1 nm

The reason why under the completely same processing conditions, the SiN film was rarely formed on the Si substrate and the SiN film was formed on the TiN film is because the Ti included in the TiN film acts as a catalyst and accelerates the decomposition of the amine-based Si raw material gas. Furthermore, as indicated by the arrow in FIG. 4, there is a clear trend for the SiN film, which is certainly formed on the TiN film, to become thicker as the number of cycles increase.

These results show that when forming a TiSiN film according to the first embodiment, it may be preferable to supply the amine-based Si raw material gas and nitriding gas after the TiN film is formed on a surface to be processed of the object to be processed.

### <TiSiN Film Characteristics>

The characteristics of the TiSiN film (formed by the method of forming a TiSiN film according to the first embodiment) and the characteristics of the TiN film are compared and described below.

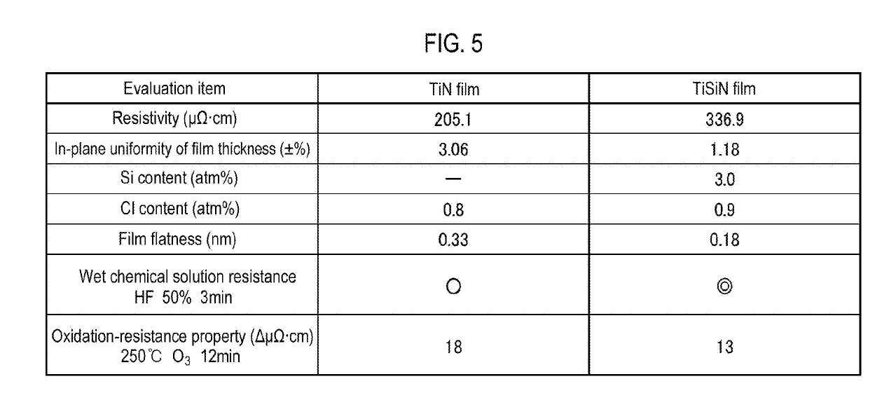

FIG. 5 compares the characteristics of the TiN film and the TiSiN film.

As illustrated in FIG. 5, the TiN film had specific resistivity of 205.1 μΩ·cm, whereas the TiSiN film's specific resistivity was 336.9 μΩ·cm. The TiSiN film has a higher specific resistivity than the TiN film because it includes Si. Resistivity tends to increase as the Si concentration is increased. In this aspect, the TiSiN film formed by the method of forming a TiSiN film according to the first embodiment can minimize the increase in specific resistivity because the TiSiN film can have a lower Si concentration than when using a Cl-based Si raw material gas, for example.

The in-plane uniformity of the film thickness was 3.06±% in the TiN film, whereas it was 1.18±% in the TiSiN film. The TiSiN film formed by the method of forming a TiSiN film according to the first embodiment can have excellent in-plane uniformity of the film thickness compared to the TiN film.

The TiSiN film has an Si content of 3.0 atm %. This value may be lower than that of a TiSiN film formed using the Cl-based Si raw material gas. The TiN film did not include any Si.

The TiN film had a chlorine (Cl) content of 0.8 atm %, whereas the TiSiN film had CI content of 0.9 atm %. The films both had almost the same CI content. The TiSiN film formed by the method of forming a TiSiN film according to the first embodiment can limit the Cl content which may affect film quality. Furthermore, a TiSiN film formed using a Cl-based Si raw material gas will have higher Cl content than the TiN film.

The TiN film had film flatness of 0.33 nm, whereas the TiSiN film had film flatness of 0.18 nm It was found that the TiSiN film formed by the method of forming a TiSiN film according to the first embodiment has improved film flatness compared to the TiN film.

While the TiN film had good wet chemical solution resistance, the TiSiN film formed by the method of forming a TiSiN film according to the first embodiment had a better chemical resistance property than the TiN film.

The oxidation-resistance of the films was determined by the increase of specific resistivity. The TiN film had an oxidation-resistance property of 18 ΔμΩ·cm, whereas the TiSiN film had an oxidation-resistance property of 13 ΔμΩ·cm. The TiSiN film formed by the method of forming a TiSiN film according to the first embodiment had a better oxidation-resistance than the TiN film.

### The Second Embodiment

### <Film Forming Apparatus>

Hereinafter, a film forming apparatus capable of performing the method of forming a TiSiN film in accordance with the first embodiment of the present disclosure is described as a second embodiment of the present disclosure.

### FIRST EXAMPLE

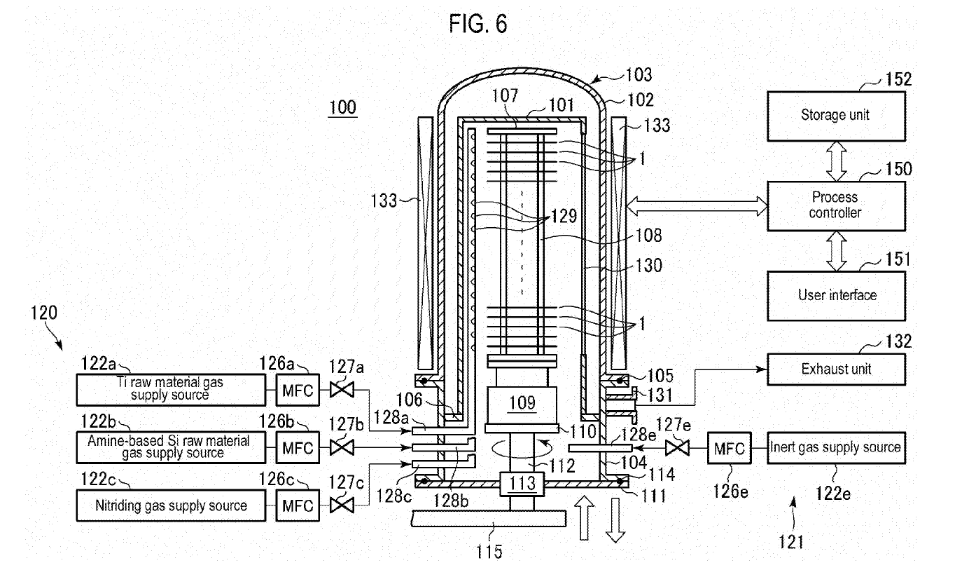

FIG. 6 is a longitudinal cross-sectional view schematic illustrating the first example of the film forming apparatus of the second embodiment.

FIG. 6 shows a film forming apparatus 100. The film forming apparatus 100 includes a processing chamber 103 with a dual barrel structure that includes an inner tube 101 configured to have a bottom open and to have a cylindrical shape having a ceiling and an outer tube 102 that is disposed in a concentric shape outside the inner tube 101. The inner tube 101 and the outer tube 102 may be made of quartz, for example. A manifold 104 connects to the bottom of the outer tube 102 of processing chamber 103 through a seal member 105, such as an O-ring. The manifold 104 can be made of stainless steel, for example, and has a cylindrical shape. The inner tube 101 of processing chamber 103 is supported on a support ring 106 installed on the inner wall of the manifold 104.

The bottom of the manifold 104 is open. A vertical type wafer boat 107 is inserted into the inner tube 101 through the opening at the bottom of the manifold 104. The vertical type wafer boat 107 includes a plurality of rods 108 in which a plurality of support grooves (not illustrated) are formed. A plurality (e.g., 50 to 100) of objects to be processed (such as wafers 1), are mounted on the support grooves. In this example, the support grooves support the periphery portions of the wafers 1, which are carried on the vertical type wafer boat 107 in multiple stages in the vertical direction.

The vertical type wafer boat 107 is carried on a table 110 with a heat insulation tube 109 made of quartz interposed between them. The table 110 is supported by a rotation shaft 112 that penetrates a cover unit 111 made of stainless steel, for example, and configured to open and close the opening at the bottom of the manifold 104. The penetration portion of the rotation shaft 112 can have, for example, a magnetic fluid seal 113 which rotatably supports the rotation shaft 112 while air tightly sealing the rotation shaft 112. A seal member 114, such as an O-ring, is installed between the periphery of the cover unit 111 and the bottom of the manifold 104. Accordingly, sealing within the processing chamber 103 is maintained. The rotation shaft 112 is installed at the end of an arm 115 supported by an elevator system (not illustrated), such as a boat elevator. Accordingly, the vertical type wafer boat 107 and the cover unit 111 can be raised or lowered together as a unit by the elevator system, and thereby inserted into or removed from the inner tube 101 of the processing chamber 103.

The film forming apparatus 100 further includes a processing gas supply mechanism 120 for supplying gas to be used for processing to the inner tube 101 and an inert gas supply mechanism 121 for supplying an inert gas to the inner tube 101.

The processing gas supply mechanism 120 includes a Ti raw material gas supply source 122a that is a Ti raw material gas supply source, an amine-based Si raw material gas supply source 122b that is an amine-based Si raw material gas supply raw material, and a nitriding gas supply source 122c that is a nitriding gas supply source.

The Ti raw material gas supply source 122a is connected to a dispersion nozzle 128a through a mass flow controller (MFC) 126a and an open/close valve 127a. The amine-based Si raw material gas supply source 122b is connected to a dispersion nozzle 128b through an MFC 126b and an open/close valve 127b. The nitriding gas supply source 122c is connected to a dispersion nozzle 128c through an MFC 126c and an open/close valve 127c.

The inert gas supply mechanism 121 includes an inert gas supply source 122e. An example of the inert gas may include a nitrogen (N₂) gas. The inert gas is used to purge the inner tube 101. The inert gas supply source 122e is connected to a nozzle 128e through an MFC 126e and an open/close valve 127e.

Each of the dispersion nozzles 128a to 128c may be formed of, for example, quartz pipes. These dispersion nozzles are configured to penetrate the inside sidewall of the manifold 104, and bend towards the inner tube 101 within the manifold 104 in the height direction, and extend vertically. A plurality of gas discharge holes 129 are formed in the vertical sections of dispersion nozzles 128a to 128c at specific intervals. Accordingly, each gas is uniformly discharged horizontally from the gas discharge holes 129 to the inside of the inner tube 101. Furthermore, the nozzle 128e penetrates the sidewall of the manifold 104 and horizontally discharges the inert gas from its tip.

An exhaust port 130 for discharging for the inner tube 101 is formed in the sidewall of the inner tube 101 which is placed on the side opposite the dispersion nozzles 128a to 128c. The inner tube 101 communicates with the inside of the outer tube 102 through the exhaust port 130. The inside of the outer tube 102 communicates with a gas outlet 131 formed on the sidewall of the manifold 104. An exhaust unit 132 including a vacuum pump is connected to the gas outlet 131. The exhaust unit 132 exhausts the inside of the outer tube 102 and also exhausts the inside of the inner tube 101 through the exhaust port 130. Accordingly, the exhaust unit 132 can discharge used processing gasses from the inner tube 101 or adjust the pressure within the inner tube 101.

A heating unit 133 having a cylindrical body shape is installed on the outer periphery of the outer tube 102. The heating unit 133 activates gasses supplied into the inner tube 101 and also heats the wafers 1 received in the inner tube 101.

The elements of the film forming apparatus 100 are controlled by a process controller 150 formed of a microprocessor (computer), for example. A touch panel that enables an operator to manage the film forming apparatus 100 by performing manipulations and inputting commands, or a user interface 151, which includes a display for visualizing and displaying the operating conditions of the film forming apparatus 100, is connected to the process controller 150.

A storage unit 152 is connected to the process controller 150. The storage unit 152 stores recipies. The recipies include control programs that run various processes executed in the film forming apparatus 100 under the control of the process controller 150, as well as programs for controlling the components of film forming apparatus 100 in response to processing conditions. The recipe may be stored, for example in a storage medium of the storage unit 152. The storage medium may be a hard disk or semiconductor memory or a portable device, such as CD-ROM, a DVD, or flash memory. Furthermore, the recipe may be properly transmitted by another device, for example, through a dedicated line. A recipe may be read from the storage unit 152 in response to an instruction from the user interface 151, if necessary, and the process controller 150 will execute processing according to the recipe read from storage unit 152. Accordingly, the film forming apparatus 100 performs the desired film formation processing under the control of the process controller 150, for example, Steps S1 to S11 described with reference to FIG. 1

The method of forming a TiSiN film in accordance with the first embodiment of the present disclosure may be performed by the film forming apparatus 100, such as that illustrated in FIG. 6.

### SECOND EXAMPLE

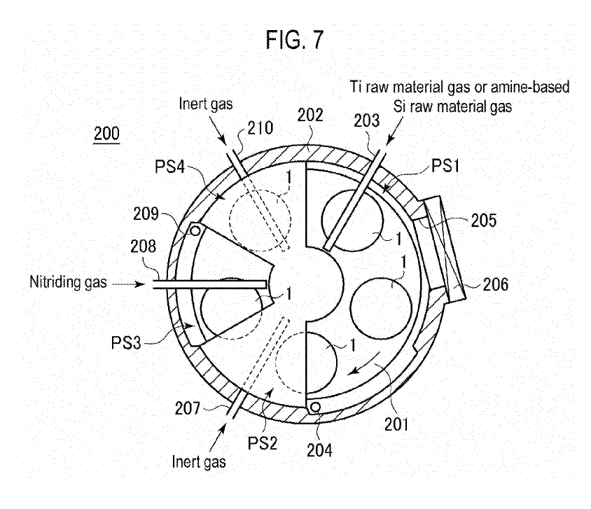

FIG. 7 is a horizontal cross-sectional view schematically illustrating a second example of a film forming apparatus in accordance with the second embodiment of the present disclosure.

The film forming apparatus is not limited to vertical batch types, such as those illustrated in FIG. 6. For example, the film forming apparatus may also be a horizontal batch type, such as that illustrated in FIG. 7. FIG. 7 schematically illustrates the horizontal cross section of the processing chamber of a horizontal batch type film forming apparatus 200. In FIG. 7, the exhaust unit, the heating unit, and the controller are not illustrated.

As illustrated in FIG. 7, the film forming apparatus 200 carries and processes, for example, 5 sheets of the wafers 1 on a turn table 201. The turn table 201 is rotated clockwise while it carries the wafers 1. The processing chamber 202 of the film forming apparatus 200 may be divided into four processing stages PS1 to PS4. When the turn table 201 is rotated, the wafers 1 sequentially circulate through the four processing stages from PS1 to PS4.

The first processing stage PS1 performs either Step S1 or Step S6 of FIG. 1. In processing stage PS1, a Ti raw material gas or an amine-based Si raw material gas is supplied onto a surface of the wafer 1 to be processed. A gas supply pipe 203, located on the upper side of processing stage PS1, supplies the Ti raw material gas or the amine-based Si raw material gas. The gas supply pipe 203 supplies the Ti raw material gas or the amine-based Si raw material gas towards the surface of the wafer 1 to be processed. Wafer 1 is carried into the processing stage PS1 when the turn table 201 rotates. An exhaust port 204 is formed on the downstream side of processing stage PS1.

Furthermore, the processing stage PS1 may be a carry-in/carry-out stage for placing the wafer 1 into the processing chamber 202 or removing the wafer 1 from the processing chamber 202. The wafer 1 is carried in or out the processing chamber 202 through the carry-in/carry-out hole 205. The carry-in/carry-out hole 205 is opened and closed by the gate valve 206. The next stage after processing stage PS1 is processing stage PS2.

The processing stage PS2 performs either Step S2 or Step S7 of FIG. 1. The processing stage PS2 has a narrow space. In this state, the wafer 1 exits from the narrow space on the turn table 201. An inert gas is supplied into the narrow space from the gas supply pipe 207. The next stage after processing stage PS2 is processing stage PS3.

The processing stage PS3 performs either Step S3 or Step S8 of FIG. 1. A gas supply pipe 208, located on the upper side of the processing stage PS3, supplies a nitriding gas towards the surface of the wafer 1 to be processed. The wafer 1 is carried into processing stage PS3 when the turn table 201 rotates. An exhaust port 209 is formed on the downstream side of processing stage PS3. The next stage after processing stage PS3 is processing stage PS4.

The processing stage PS4 is a stage for performing Step S4 or Step S9 illustrated in FIG. 1. As in the processing stage PS2, the processing stage PS4 has a narrow space. The wafer 1 exits from the narrow space on the turn table 201. An inert gas is supplied into the narrow space from the gas supply pipe 210. After the processing stage PS4, processing returns to the first stage, processing stage PS1.

As described above, as the wafer 1 returns after a single turn, the film forming apparatus 200 completes Steps S1 to S4 or Steps S6 to S9 of FIG. 1. That is, when the wafer 1 goes through a full rotation of the turn table 201, one cycle is completed.

The method of forming a TiSiN film in accordance with the first embodiment of the present disclosure may also be performed using a film forming apparatus 200, such as the one shown in FIG. 7. Furthermore, a single wafer processing type of film forming apparatus, which is not a batch type apparatus, may also perform the embodiment of the present disclosure.

Although some embodiments of the present disclosure have been described, the present disclosure is not limited to the embodiments and may be modified in various ways without departing from the scope of the present disclosure.

For example, in the embodiments, 3DMAS has been used as the amine-based Si raw material gas, but other amine-based Si raw material gas may also be used. For example, the amine-based Si raw material gas may include the following gasses:

BAS (butylaminosilane)

BTBAS (bis(tertiarybutylamino)silane)

DMAS (dimethylaminosilane)

BDMAS (bis(dimethylamino)silane)

TDMAS (tris(dimethylamino)silane)

DEAS (diethylaminosilane)

BDEAS (bis(diethylamino)silane)

DPAS (dipropylaminosilane)

DIPAS (diisopropyl aminosilane)

((R1R2)N)ₙSi_{X}H_{2X+2-n-m}(R3)ₘ (A)

((R1R2)N)ₙSi_{X}H_{2X-n-m}(R3)ₘ (B)

In formulas A and B,

n is a number from 1 to 6, indicating the number of amino groups.

m is a number from 0 to 5, indicating the number of alkyl groups.

R1, R2 and R3 are each independently selected from a group consisting of CH₃, C₂H₅ and C₃H₇,

X is a number equal to or greater than 2.

Examples of the aminosilane-based gas expressed by formula A may include:

hexakisethylaminodisilane (Si₂H₆N₆(Et)₆),

diisopropylaminodisilane (Si₂H₅N(iPr)₂),

diisopropylaminotrisilane (Si₃H₇N(iPr)₂),

diisopropylaminodichlorosilane (Si₂H₄ClN(iPr)₂), and

diisopropylaminotrochlorosilane (Si₃H₆ClN(iPr)₂).

Furthermore, examples of the aminosilane-based gas expressed by Formula B may include:

diisopropylaminodisilane (Si₂H₃N(iPr)₂) and

diisopropylaminocyclotrisilane (Si₃H₅N(iPr)₂).

Furthermore, although the detailed processing conditions have been illustrated in the first embodiment, the processing conditions may be appropriately changed depending on the size of an object to be processed or the capacity of a processing chamber.

In addition, the present disclosure may be properly changed without departing from the gist of the present disclosure.

In accordance with the present disclosure, there can be provided the method of forming a TiSiN film, which is capable of more finely controlling a Si concentration, and the film forming apparatus capable of executing the same.

While certain embodiments have been described, these embodiments have been presented by way of example only, and are not intended to limit the scope of the present disclosure. Indeed, the embodiments described herein may be embodied in a variety of other forms. Furthermore, various omissions, substitutions and changes in the form of the embodiments described herein may be made without departing from the spirit of the present disclosure. The appended claims and their equivalents are intended to cover such forms or modifications as would fall within the scope and spirit of the present disclosure.

What is claimed is:

1. A method of forming a TiSiN film on a surface of an object to be processed, the method comprising:
repeating a first cycle a first predetermined number of times, the first cycle including supplying a Ti raw material gas containing Ti raw material into a processing chamber where the object to be processed is accommodated, and supplying nitriding gas containing a nitridant into the processing chamber after the Ti raw material gas is supplied into the processing chamber; and
repeating a second cycle a second predetermined number of times after repeating the first cycle the first predetermined number of times, the second cycle including supplying a Si raw material gas containing Si raw material into the processing chamber, and supplying a nitriding gas containing a nitridant into the processing chamber after the Si raw material gas is supplied into the processing chamber,
wherein the Si raw material gas comprises an amine-based Si raw material gas.

2. The method of claim 1, comprising:
repeating a third cycle a third predetermined number of times, the third cycle including repeating the first cycle the first predetermined number of times and repeating the second cycle the second predetermined number of times, so that a thickness of the TiSiN film reaches a set thickness.

3. The method of claim 1, wherein repeating the first cycle the first predetermined number of times includes forming a TiN film.

4. The method of claim 3, wherein repeating the second cycle the second predetermined number of times is performed after forming the TiN film on the surface of the object to be processed.

5. The method of claim 1, wherein the amine-based Si raw material gas comprises:
BAS (butylaminosilane)
BTBAS (bis(tertiarybutylamino)silane)
DMAS (dimethylaminosilane)
BDMAS (bis(dimethylamino)silane)
TDMAS (tris(dimethylamino)silane)
DEAS (diethylaminosilane)
BDEAS (bis(diethylamino)silane)
DPAS (dipropylaminosilane)
DIPAS (diisopropyl aminosilane)
((R1R2)N)ₙSi_{X}H_{2X+2-n-m}(R3)ₘ (A)
((R1R2)N)ₙSi_{X}H_{2X-n-m}(R3)ₘ (B)
where, in formulas A and B,
n is a number from 1 to 6, indicating the number of amino groups
m is a number from 0 to 5, indicating the number of alkyl groups
R1, R2 and R3 are each independently selected from a group consisting of CH₃, C₂H₅ and C₃H₇, and
X is a natural number equal to or greater than 2.

6. A film forming apparatus for forming a TiSiN film on a surface of an object to be processed, the apparatus comprising:
a processing chamber that accommodates the object to be processed;
a gas supply mechanism that supplies a Ti raw material gas, a nitriding gas, and an amine-based Si raw material gas into the processing chamber;
a heating unit that heats an interior of the processing chamber;
an exhaust unit that exhausts the interior of the processing chamber; and
a controller that controls the gas supply mechanism, the heating unit, and the exhaust unit,
wherein the controller controls the gas supply mechanism, the heating unit, and the exhaust unit so that the method of claim 1 is performed on the object to be processed in the processing chamber.
